(19) United States
(12) Patent Application Publication
(10) Pub. No.: US 2006/0154425 A1
(43) Pub. Date: Jul. 13, 2006

(54) Semiconductor device and method for fabricating the same

(75) Inventors: Ming-Ho Yang, Hsinchu (TW); Karen Mai, Chunghe City (TW); Liang-Gi Yao, Hsinchu City (TW); Shih-Chang Chen, Taoyuan City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/032,439

(22) Filed: Jan. 10, 2005

(51) Int. Cl. H01L 21/336

(52) U.S. Cl. 438/287

(57) ABSTRACT

A semiconductor device and method for fabricating the same. The semiconductor device comprises a substrate with a gate stack thereon, wherein the gate stack comprises a high-k dielectric layer and a conductive layer sequentially overlying a portion of the substrate. An oxidation-proof layer overlies sidewalls of the gate stack. A pair of insulating spacers oppositely overlies sidewalls of the gate stack and the oxidation-proof layers thereon and a pair of source/drain regions is oppositely formed in the substrate adjacent to the gate stack, wherein the oxidation-proof layer suppresses oxidation encroachment between the gate stack and the substrate.

### BACKGROUND

The present invention relates to semiconductor devices, and in particular to semiconductor devices having MOS transistors in which corner edges of the gate stack thereof are protected from undesired oxidation encroachment and methods for fabricating the same.

In modern semiconductor devices, bulk silicon is used as a substrate and higher operating speed and lower energy consumption can be achieved by size reduction of the semiconductor device, such as metal-oxide-semiconductor field-effect transistors (MOSFETs), formed thereon. Size reduction of MOSFETs, however, is limited by the very thin silicon dioxide based gate dielectrics thereof and may experience unacceptable gate leakage currents. Thus, forming gate dielectrics from certain dielectric materials with a high dielectric constant (high-k), instead of silicon dioxide, can be chosen to reduce gate leakage.

Nevertheless, one of the issues related to using high-k dielectric material for gate dielectrics is the formation of bird's beak encroachment at the corner edge of the gate stack due to lateral encroachment of the formed SiO₂ under the high-k material. The bird's beak encroachment typically has a tapered shape. The formation of the SiO₂ bird's peak directly under the corner of the gate stack will significantly reduce the effective k-value and thereby increase the gate equivalent oxide thickness (EOX). Such bird's beak encroachment is thus unacceptable for CMOS transistor manufacturing.

FIG. 1 is a diagram illustrating a gate stack formed over a substrate 10, using a high-k gate dielectric layer 12, having SiO₂ encroachment as found in conventional semiconductor devices. The lateral encroachment 16, which is also typically referred to as “bird's beak” encroachment, is demonstrated under the high-k gate dielectric layer 12. The bird's beak encroachment is formed directly under a gate electrode 14 and thus reduces the dielectric constant of the dielectric layer between the gate electrode and the active regions. That is, the permittivity (k) of the SiO₂ is less than that of a typical high-k dielectric material. High-k materials, for example, are typically described as having k values greater than 3.9, which is the k value of SiO₂.

The lateral encroachment 16 of the high-k gate dielectric layer 12 effectively increases the effective oxide thickness (EOT) of the gate stack in the locations where the encroachment is presented. This undermines the effectiveness of the high-k gate dielectric layer 12. As device miniaturization continues, gate dielectric materials with higher permittivity values are selected because they can be deposited in thicker layers (and thereby avoiding electron tunneling and other problems) while retaining the electrical characteristics of a thinner gate dielectric layer. Unfortunately, the presence of lateral encroachment reduces the advantages of the high-k gate dielectric layer by reducing the overall dielectric constant thereof combining the high-k and encroachment regions.

### SUMMARY

Semiconductor devices and methods for fabricating the same are provided. An exemplary method for fabricating a semiconductor device is provided, comprising providing a substrate with a high-k dielectric layer and a conductive layer sequentially formed thereon. The conductive layer and the high-k dielectric layer overlying the substrate are patterned and etched to form a gate stack. An oxidation-proof layer and an insulating layer are sequentially formed over the substrate, wherein the oxidation-proof layer conformably covers exposed surfaces of the gate stack thereby suppressing oxidation encroachment between the gate stack and the substrate.

A semiconductor device is also provided, comprising a substrate with a gate stack thereon, wherein the gate stack comprises a high-k dielectric layer and a conductive layer sequentially overlying a portion of the substrate. An oxidation-proof layer overlies sidewalls of the gate stack. A pair of insulating spacers oppositely overlie sidewalls of the gate stack and the oxidation-proof layers thereon and a pair of source/drain regions oppositely formed in the substrate adjacent to the gate stack, wherein the oxidation-proof layer suppresses oxidation encroachment between the gate stack and the substrate.

A detailed description is given in the following embodiments with reference to the accompanying drawings.

### BRIEF DESCRIPTION OF THE DRAWINGS

The invention can be more fully understood by reading the subsequent detailed description and examples with reference made to the accompanying drawings, wherein:

FIG. 1 is a cross section showing a related art MOS transistor, having high-k gate dielectric with SiO2 encroachment;

FIGS. 2-5 are cross sections showing a method for forming a semiconductor device according to an embodiment of the invention.

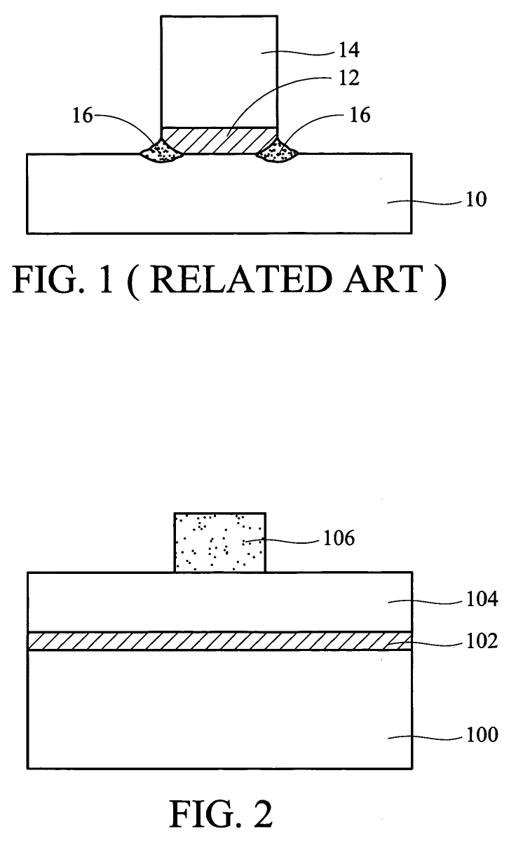

### DESCRIPTION

In this specification, expressions such as “overlying the substrate”, “above the layer”, or “on the film” simply denote a relative positional relationship with respect to the surface of the base layer, regardless of the existence of intermediate layers. Accordingly, these expressions may indicate not only the direct contact of layers, but also, a non-contact state of one or more laminated layers. Use of the term “high dielectric constant” or “high-k” herein, means a dielectric constant (k value) which is larger than the dielectric constant of a conventional silicon oxide. Preferably, the high-k dielectric constant is greater than about 8.0.

FIGS. 2-5 are cross sections showing fabrication steps of a method for fabricating a semiconductor device.

In FIG. 2, a substrate 100 of a semiconductor material is provided. The first semiconductor material of the substrate 100 can be elemental, alloy or compound semiconductor material and is preferably an elemental semiconductor material such as silicon.

Next, a dielectric layer 102 and a conductive layer 104 are sequentially formed over the substrate 100. A resist pattern 106 is then formed over a portion of the conductive layer 104 for patterning of a gate stack. The dielectric layer 102 is a high-k dielectric layer including high permittivity (high-k) material with a relative permittivity greater than 8 such as aluminum oxide (Al₂O₃), hafnium oxide (HfO₂), zirconium oxide (ZrO₂), hafnium oxynitride (HfON), hafnium silicate (HfSiOₓ), zirconium silicate (ZrSiO₄), lanthanum oxide (La₂O₃), or combinations thereof. The dielectric layer 102 is formed at an equivalent oxide thickness (EOT) of about 3 Å to 100 Å and can be formed in a single or laminated layer.

The dielectric layer 102 can be formed by chemical vapor deposition such as atomic layer chemical vapor deposition (ALCVD), metal organic chemical vapor deposition (MOCVD), physical vapor deposition such as sputtering, or other known techniques to form a high-k dielectric layer.

Moreover, the conductive layer 104 can be a single dielectric layer of dopant doped polysilicon (poly-Si), metal such as molybdenum or tungsten, metal compounds such as titanium nitride, or other conductive materials. The conductive layer 104 can be also a composite layer of combinations of the described conductive materials.

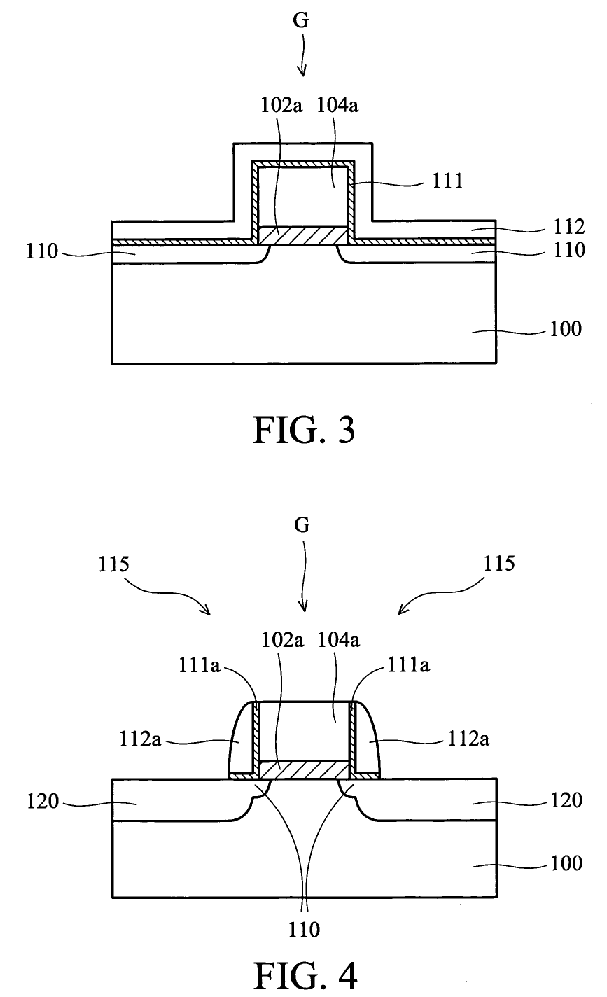

In FIG. 3, an etching such as anisotropic etching (not shown) is then performed to the conductive layer 104 and the high-k dielectric layer 102, using the resist pattern as an etching mask, thereby forming a gate stack G over a portion of the substrate 100, including a gate dielectric 102a and a gate electrode 104a. Next, a pair of lightly doped source/drain regions 110 is formed in the substrate 100 by ion implantation, using the gate stack G as an implant mask.

Next, an oxidation-proof layer 111 and an insulating layer 112 are then sequentially and conformably formed over the substrate 100. The oxidation-proof layer 111 and the insulating layer 112 conformably cover exposed surfaces of the gate stack G and extend to the adjacent substrate 100. Herein, the oxidation-proof layer 112 can be a silicon nitride or silicon oxynitride layer to provide better passivation against the oxidation encroachment near the bottom corners of the gate stack G during the sequential formation of the insulating layer 112. The oxidation-proof layer is formed at a thickness of about 5 Å to 100 Å, preferably of about 20 Å to 60 Å. In addition, the insulating layer 112 can be, for example, a single layer of oxide (abbreviated as O) such as silicon oxide or nitride (abbreviated as N) such as silicon nitride. The insulating layer 112 can also be a composite layer of oxide-nitride (ON) or oxide-nitride-oxide (ONO). A method for forming the oxidation-proof layer 111 can be chemical vapor deposition (CVD) such as metal organic chemical vapor deposition (MOCVD) and the oxidation-proof layer 111 may formed with a thicker horizontal portion overlying the substrate 100 and the gate electrode 104a and thinner vertical portions over a sidewall of the gate stack G.

In FIG. 4, an etching procedure, such as, anisotropic etching (not shown) is then performed on the insulating layer 112 and the oxidation-proof layer 111, stopping at the gate electrode 104a and substrate 100. A pair of insulating spacers 115 is thereby formed on sidewalls of the gate stack G, each including a patterned oxidation-proof layer 111a and a patterned insulating layer 110a. The oxidation-proof layer 111a is formed on the sidewall of the gate stack G and a portion of the substrate 100 adjacent thereto and the patterned insulating layer 110a is formed over each oxidation-proof layer 111a, thereby forming the insulating spacer 115.

Next, another ion implantation procedure is performed to form a pair of heavily doped source/drain regions 120 in the substrate 100 thereby forming a MOS transistor over the substrate 100. When using high-k dielectric materials, the gate dielectric 102a is passivated by the oxidation-proof layer 112a. Undesirable oxidation encroachments occuring between the high-k gate dielectric and the underlying substrate during the formation of the insulating spacers 115 are thus prevented. Increased effective oxide thickness (EOT) of the high-k gate dielectric and reduced dielectric constant of the high-k dielectric may also be prevented.

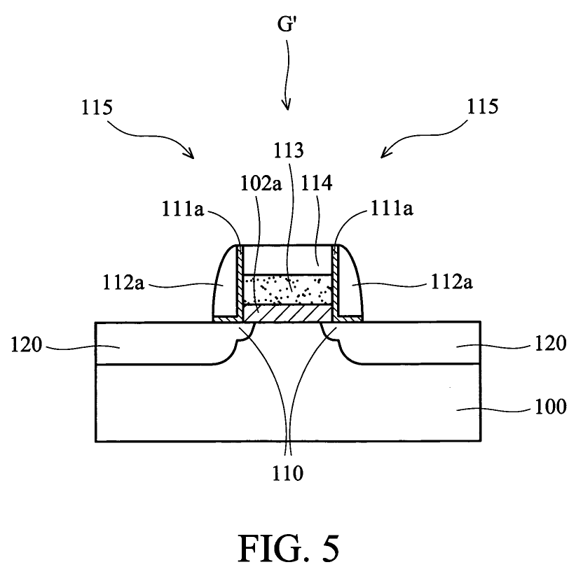

In FIG. 5, a MOS transistor with a gate stack G′ different than that of FIG. 4 is illustrated. The gate stack G′ comprises a composite layer including a metal layer 113 and an overlying polysilicon layer 114.

As shown in FIG. 4, a semiconductor device with a high-k gate dielectric layer is illustrated. The semiconductor device includes a substrate with a gate stack thereon, wherein the gate stack comprises a high-k dielectric layer and a conductive layer sequentially overlying a portion of the substrate. An oxidation-proof layer overlies sidewalls of the gate stack. A pair of insulating spacers respectively overlies a sidewall of the gate stack and the oxidation-proof layer thereon. A pair of source/drain regions is oppositely formed in the substrate adjacent to the gate stack, wherein the oxidation-proof layer suppresses oxidation encroachment between the gate stack and the substrate.

The oxidation-proof layer 111a in FIGS. 4 and 5 may prevent undesirable oxidation encroachments occurring between the high-k gate dielectric and the substrate and/or between the high-k gate dielectric the gate electrode during formation of the insulating spacers. Reduction of the lateral encroachment of the high-k dielectric layer which effectively increases the effective oxide thickness (EOT) of the gate stack and reduces the overall dielectric constant of the high-k in the semiconductor device.

The method for preventing the described disadvantage of the oxidation encroachment between the high-k dielectric layer and the substrate forms conformal oxidation-proof layer on exposed surfaces of a gate stack prior to the formation of insulating spacers. Thus, the substrate near the corner edges of the gate stack are sealed from the atomic oxygen in the oxygen-containing ambient atmosphere and undesirable bird's beak encroachments are thus prevented.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a semiconductor device, comprising:
providing a substrate with a high-k dielectric layer and a conductive layer sequentially formed thereon;
patterning and etching the conductive layer and the high-k dielectric layer over the substrate thereby forming a gate stack; and
sequentially forming an oxidation-proof layer and an insulating layer over the substrate, wherein the oxidation-proof layer conformably covers exposed surfaces of the gate stack thereby suppressing oxidation encroachment between the gate stack and the substrate.

2. The method of claim 1, further comprising etching the insulating layer and the oxidation-proof layer to form insulating spacers on sidewalls of the gate stack.

3. The method of claim 1, wherein the high-k dielectric layer is formed by atomic layer chemical vapor deposition (ALCVD) or metal organic chemical vapor deposition (MOCVD).

4. The method of claim 1, wherein the high-k dielectric layer has an equivalent oxide thickness of about 3 Å to 100 Å.

5. The method of claim 1, wherein the high-k dielectric layer comprises aluminum oxide (Al₂O₃), hafnium oxide (HfO₂), zirconium oxide (ZrO₂), hafnium oxynitride (HfON), hafnium silicate (HfSiOₓ), zirconium silicate (ZrSiO₄), lanthanum oxide (La₂O₃), or combinations thereof.

6. The method of claim 1, wherein the insulating layer comprises nitride, oxide or combinations thereof.

7. The method of claim 1, wherein the oxidation-proof layer comprises silicon nitride or silicon oxynitride.

8. The method of claim 1, wherein the oxidation-proof layer has a thickness of about 5 Å to 100 Å.

9. The method of claim 1, wherein the oxidation-proof layer extends to the substrate adjacent to the gate stack.

10. The method of claim 9, wherein the oxidation-proof layer has a thinner vertical portion overlying sidewalls of the gate stack and a thicker horizontal portion overlying the substrate.

11. A semiconductor device, comprising:
a substrate with a gate stack thereon, wherein the gate stack comprises a high-k dielectric layer and a conductive layer sequentially overlying a portion of the substrate;
an oxidation-proof layer overlying sidewalls of the gate stack;
a pair of insulating spacers oppositely overlying sidewalls of the gate stack and the oxidation-proof layers thereon; and
a pair of source/drain regions oppositely in the substrate adjacent to the gate stack, wherein the oxidation-proof layer suppresses oxidation encroachment between the gate stack and the substrate.

12. The semiconductor device of claim 11, wherein the high-k dielectric layer has an equivalent oxide thickness of about 3 Å to 100 Å.

13. The semiconductor device of claim 11, wherein the high-k dielectric layer comprises aluminum oxide (Al₂O₃), hafnium oxide (HfO₂), zirconium oxide (ZrO₂), hafnium oxynitride (HfON), hafnium silicate (HfSiOₓ), zirconium silicate (ZrSiO₄), lanthanum oxide (La₂O₃), or combinations thereof.

14. The semiconductor device of claim 11, wherein the insulating spacers comprise nitride, oxide or combinations thereof.

15. The semiconductor device of claim 11, wherein the oxidation-proof layer comprises silicon nitride or silicon oxynitride.

16. The semiconductor device of claim 11, wherein the oxidation-proof layer has a thickness of about 5 Å to 100 Å.

17. The semiconductor device of claim 11, wherein the oxidation-proof layer extends to the substrate adjacent to the gate stack.

18. The semiconductor device of claim 17, wherein the oxidation-proof layer has a thinner vertical portion overlying sidewalls of the gate stack and a thicker horizontal portion overlying the substrate.
